(19) United States
(12) Patent Application Publication
(10) Pub. No.: US 2013/0269776 A1
(43) Pub. Date: Oct. 17, 2013

(54) SILANE-CONTAINING THERMOPLASTIC POLYOLEFIN COPOLYMER RESINS, FILMS, PROCESSES FOR THEIR PREPARATION AND PHOTOVOLTAIC MODULE LAMINATE STRUCTURE COMPRISING SUCH RESINS AND FILMS

(71) Applicants: Shaofu Wu, Sugar Land, TX (US); Lih-Long Chu, Midland, MI (US); John D. Weaver, Pearland, TX (US); John A. Naumovitz, Midland, MI (US); Richard C. Abel, Lake Jackson, TX (US)

(72) Inventors: Shaofu Wu, Sugar Land, TX (US); Lih-Long Chu, Midland, MI (US); John D. Weaver, Pearland, TX (US); John A. Naumovitz, Midland, MI (US); Richard C. Abel, Lake Jackson, TX (US)

(73) Assignee: DOW GLOBAL TECHNOLOGIES LLC, Midland, MI (US)

(21) Appl. No.: 13/994,315

(22) PCT Filed: Nov. 8, 2011
(86) PCT No.: PCT/US11/59690

§ 371 Date: Jun. 14, 2013

Related U.S. Application Data
(60) Provisional application No. 61/423,840, filed on Dec. 16, 2010.

(51) Int. Cl. H01L 31/048; H01L 31/18

(52) U.S. Cl. CPC H01L 31/0481; H01L 31/1876
USPC 136/256; 428/220; 524/576; 438/66

(57) ABSTRACT

Disclosure are films based on alkoxysilane-containing polyolefin resins with reduced melt strength, photovoltaic cell laminate structures and methods for their preparation. In the disclosed alkoxysilane-containing polyolefin resin films according to the invention, reduced melt strength is provided by, among other things, using optimized silane:initiator ratios and is shown to reduce detrimental film shrinkage and provide improved photovoltaic laminate structures.

### CROSS-REFERENCE TO RELATED APPLICATIONS

This application claims priority from provisional application Ser. No. 61/423,840, filed Dec. 16, 2010, which is incorporated herein by reference in its entirety.

### FIELD OF THE INVENTION

The present invention relates to improved alkoxysilane-containing thermoplastic polyolefin copolymer resins and films of those resins for photovoltaic cell encapsulation, including particularly for light transmitting layers in photovoltaic module structures. This includes the alternative embodiments of: (i) a process for maintaining reduced encapsulating film shrinkage by optimizing the alkoxysilane-containing thermoplastic polyolefin copolymer resin in terms of alkoxysilane content and melt strength, (ii) a process for making photovoltaic module laminate structures having at least one layer of such film and (iii) a photovoltaic module laminate structure having at least one layer of such film.

### BACKGROUND OF THE INVENTION

It is known from WO 2008/036707, WO 2008/036708, and WO2010/009017 to employ alkoxysilane-containing thermoplastic polyolefin resin films as encapsulant films or layers in a photovoltaic (PV) panel or module. Encapsulation film layers are needed to adhere the interior photovoltaic cell to other layers in laminate structures, for example, to glass layers or other top layers in some types of PV modules. They are also very important to encapsulate the cell to protect it from moisture and other types of physical damage. This requires a good balance of adhesion, optical clarity, physical properties and physical property retention at higher temperatures, moldability and low cost. As discussed, the alkoxysilane-containing resins can be prepared from the polyolefin copolymer by a reactive extrusion grafting step utilizing a graftable alkoxysilane-containing compound and a free radical initiator compound in a fairly wide range of amounts and ratios. As taught in these references, the incorporation of alkoxysilane into a thermoplastic polyolefin copolymer film has been found to provide both improved glass adhesion properties in the thermoplastic polyolefin resin and crosslinking that provides, in turn, the thermoplastic polyolefin resin with improved and retained physical properties.

US 2006/0100385 discloses a process for providing crosslinking in polyolefin materials for making fibers and/or films noting that when polyolefins are used in fiber production using typical spinning lines, using cross-linked polyolefins leads to increased rates of fiber breaks, especially at higher line speeds. It is taught that the requirements of fiber performance and of high speed fiber production equipment necessitate certain optimized crosslinking levels in the final product so that the preferred mechanical and thermal properties are maintained.

In the rapidly expanding area of photovoltaic module production from PV cells, it is desired to obtain improved alkoxysilane-containing thermoplastic polyolefin copolymer films that would be optimized for use as an encapsulating film for the PV cells. Such films would require an optimized balance of (a) adhesive properties for the module layers and the surface layers of the photovoltaic cells, (b) moldability and stability for the complex and delicate process of photovoltaic cell lamination and module assembly, (c) physical properties, heat resistance and optical properties that are needed during module shipping and use and (d) cost effectiveness.

### BRIEF SUMMARY OF THE INVENTION

For these and other reasons, the producers of laminated PV modules and panels using film-encapsulated PV cells have a continuing interest in obtaining improved polyolefin films and film/cell laminate structures. Therefore, according to the present invention there is provided a thermoplastic, alkoxysilane-containing polyolefin copolymer comprising at least about 0.1 weight percent of alkoxysilane based on the total weight of the polyolefin, and having a melt strength of from about 2 to about 30 centiNewtons (“cN”) at 150° C.

Also provided are additional alternative embodiments of the present invention including, but not limited to:
such a copolymer comprising from about 0.1 to about 2.5 weight percent grafted alkoxysilane and having:
   (i) a density of less than about 0.910 g/cc,
   (ii) a melting point of less than about 105° C. if a random structure or less than about 125° C. if a block-type structure, and
   (iii) optionally, one or more of:
      (a) a 2% secant modulus of less than about 150 megaPascal (MPa),
      (b) a Tg of less than about −35° C.
a grafting process for preparing such thermoplastic alkoxysilane-containing polyolefin copolymers comprising the step of grafting from about 0.1 to about 2.5 weight percent alkoxysilane compound to a thermoplastic polyolefin copolymer using a free radical generating graft initiator material; wherein the free radical generating graft initiator material is used in the grafting step in an amount that provides a molar ratio of alkoxysilane compound to free radical of at least about 20:1 or greater in the grafting reaction.
a grafting process as described herein wherein the graftable alkoxysilane compound is represented by the following formula II:

CH₂═CR¹—(R²)ₘ—Si(R³)₃₋ₙ(OR⁴)ₙ II
wherein:
R¹ is H or CH₃;
R² is alkyl, aryl, or hydrocarbyl containing from 1 to 20 carbon atoms and may also include other functional groups, such as esters, amides, and ethers, among others;
m is 0 or 1;
R³ is alkyl, aryl, or hydrocarbyl containing from 1 to 20 carbon atoms;
R⁴ is alkyl or carboxyalkyl containing from 1 to 6 carbon atoms (preferably methyl or ethyl); and
n is 1, 2, or 3 (preferably 3).
a grafting process as described herein employing a thermoplastic ethylene/α-olefin copolymer characterized by: (i) a density of less than about 0.910 g/cc, (ii) a melting point of less than about 95 degrees C., and optionally, one or more of (iii)(a) a 2% secant modulus of less than about 150 megaPascal (MPa), (iii)(b) an α-olefin content of from at least about 15 to less than about 50 wt % based on the weight of the polymer, (iii)(c) a Tg of less than about −35 C, and (iii)
a thermoplastic, alkoxysilane-containing polyolefin copolymer film for photovoltaic cell encapsulation having at least one facial surface layer of a thermoplastic, alkoxysilane-containing polyolefin copolymer as described herein and having a thickness of from about 200 to about 1000 micrometers (from about 8 to about 40 mils) and having a machine direction shrinkage value less than or equal to about 20%.
a photovoltaic module comprising: A. at least one photovoltaic cell and B. a layer of a film of a thermoplastic polyolefin copolymer as described herein disposed over a light-reactive surface of the photovoltaic cell.
a photovoltaic module as described herein also comprising: C. a layer of a film of a thermoplastic polyolefin copolymer as described herein disposed over the other surface of the photovoltaic cell and D. front and back layers.
a process for preparing a photovoltaic module comprising at least one photovoltaic cell having at least one light-reactive surface, at least one layer of glass, and at least one thermoplastic polyolefin copolymer encapsulating film according Claim 1 above, the process comprising the steps of:
A. contacting a first facial surface of a first film according to Claim 1 with the light-reactive facial surface of the photovoltaic cell having at least one light-reactive surface and encapsulating the cell surface;
B. contacting a first facial surface of a second film optionally according to Claim 1 with the other facial surface of the photovoltaic cell and encapsulating the cell;
C. contacting a top sheet layer with the second facial surface of the encapsulating film(s) applied to the light-reactive surface of cell in Step A;
D. contacting a back sheet layer with the second facial surface of the film applied in Step B; and
E. lamination by compressing the layers with heating to a lamination temperature of from about 130° C. to about 170° C.

### BRIEF DESCRIPTION OF THE DRAWINGS

FIG. 1 is a schematic of one embodiment of an electronic device module of this invention, i.e., a rigid photovoltaic (PV) module.

FIG. 2 is a schematic of another embodiment of an electronic device module of this invention, i.e., a flexible PV module.

### DETAILED DESCRIPTION OF THE PREFERRED EMBODIMENT

While it has been found that alkoxysilane-containing thermoplastic polyolefin copolymer resins and their films have generally good performance in PV cell laminating and PV module applications and can be prepared to meet the requirements for adhesion, moldability, physical/optical properties, heat resistance and low cost, it has also been found that undesirable film shrinkage forces can occur during the elevated heat stages experienced while assembling into laminated structures, such as PV modules, affecting performance in its intended use. It has been observed that the film orientation and resulting shrinkage can adversely affect the adhesion of the film to other components in the laminate structure, such as glass or other rigid top or back sheet layers, and, in the case of making PV modules/panels, can adversely affect the orientation and location of the cell in the module and can damage the cell. When it is known that a film will have unacceptable shrinkage forces in the laminate structure, the film can be treated in a further heating or annealing process to relax the orientation and “heat stabilize” the films. This, however, results in an inefficient additional step and undesired additional heating (heat degradation) of the laminate structure, the heating time depending upon several factors such as film thickness and degree of the initial orientation. As described below, the present invention addresses one or more of these issues.

The following terms and definitions apply in the description of the present invention. Numerical ranges include all values from and including the lower and the upper values, in increments of one unit, provided that there is a separation of at least two units between any lower value and any higher value. As an example, if a compositional, physical or other property or process parameter, such as, for example, molecular weight, viscosity, melt index, temperature, etc., is from 100 to 1,000, it is intended that all individual values, such as 100, 101, 102, etc., and sub ranges, such as 100 to 144, 155 to 170, 197 to 200, etc., are expressly enumerated. For ranges containing values which are less than one or containing fractional numbers greater than one (e.g., 1.1, 1.5, etc.), one unit is considered to be 0.0001, 0.001, 0.01 or 0.1, as appropriate. For ranges containing single digit numbers less than ten (e.g., 1 to 5), one unit is typically considered to be 0.1. These are only examples of what is specifically intended, and all possible combinations of numerical values between the lowest value and the highest value enumerated, are to be considered to be expressly stated in this disclosure. Numerical ranges are provided within this disclosure for, among other things, density, melt index, amount of alkoxysilane groups in the thermoplastic polyolefin resin, and relative amounts of ingredients in various formulations

The term “comprising” and its derivatives are inclusive terms not intended to exclude the presence of any additional component, step or procedure, whether or not the same is specifically disclosed. In order to avoid any doubt, any process or composition described or claimed through use of the term “comprising” may include any additional steps, equipment, additive, adjuvant, or compound whether polymeric or otherwise, unless stated to the contrary. In contrast, the term “consisting of” excludes any component, step or procedure not specifically delineated or listed. Also, the intermediate term, “consisting essentially of” excludes from the scope of any succeeding recitation any other component, step or procedure that materially affects the basic and novel characteristics of the claimed invention. The term “or”, unless stated otherwise, refers to the listed members individually as well as in any combination.

“Composition” and like terms mean a mixture or formulation of two or more materials. Included in compositions are pre-reaction, reaction and post-reaction mixtures, the latter of which will include reaction products and by-products as well as unreacted components of the reaction mixture and decomposition products, if any, formed from the one or more components of the pre-reaction or reaction mixture.

“Blend”, “polymer blend” and like terms mean a composition of two or more polymers. Such a blend may or may not be miscible. Such a blend may or may not be phase separated. Such a blend may or may not contain one or more domain configurations, as determined from transmission electron spectroscopy, light scattering, x-ray scattering, and any other method known in the art. Blends are not laminates, but one or more layers of a laminate may contain a blend.

A “polymer” or stated type of polymer means a polymeric material or resin prepared by polymerizing monomers, whether all monomers are the same type as stated or including some monomeric units of a different type. The generic term polymer thus embraces the term homopolymer, usually employed to refer to polymers prepared from only one type of monomer, and the term interpolymer or copolymer as defined below. It also embraces all forms of interpolymers, e.g., random, block, etc. The terms “ethylene/α-olefin polymer”, “propylene/α-olefin polymer” and “silane copolymer” are indicative of interpolymers as described below.

“Interpolymer” or “copolymer” may be used interchangeably and refer to a polymer prepared by the polymerization of at least two different monomers. This generic term includes copolymers prepared from two or more different monomers, e.g., terpolymers, tetrapolymers, etc.

“Layer” means a single thickness, coating or stratum continuously or discontinuously spread out or covering a surface or otherwise located in a laminate structure.

“Multi-layer” means at least two layers.

“Facial surface” and like terms refer to the two major surfaces of the layers that are either an exterior or outer-facing surface of the film or are in contact with the opposite and adjacent surfaces of the adjoining layers in a laminate structure. Facial surfaces are in distinction to edge surfaces. A rectangular layer comprises two facial surfaces and four edge surfaces. A circular layer comprises two facial surfaces and one continuous edge surface.

Layers that are in “adhering contact” (and like terms), means that facial surfaces two different layers are in touching and binding contact to one another such that one layer cannot be removed for the other layer without damage to the in-contact facial surfaces of one or both layers.

“Photovoltaic cells” (“PV cells”) contain one or more photovoltaic effect materials of any of several known types. For example, commonly used photovoltaic effect materials include but are not limited to crystalline silicon, polycrystalline silicon, amorphous silicon, copper indium gallium (di)selenide (CIGS), copper indium selenide (CIS), cadmium telluride, gallium arsenide, dye-sensitized materials, and organic solar cell materials. The PV cells have at least one light-reactive surface that converts the incident light into electric current. Photovoltaic cells are well known to practitioners in this field and are generally packaged into photovoltaic modules that protect the cell(s) and permit their usage in their various application environments, typically in outdoor applications. As used herein, PV cells include the photovoltaic effect materials and any protective coating surface materials that are applied in their production.

“Photovoltaic modules” (“PV Modules”) contain one or more PV cells in protective enclosures or packaging that protect the cell units and permit their usage in their various application environments, typically in outdoor applications. Encapsulation films are typically used in modules disposed over and covering one or both surfaces of the PV cells.

In general, a broad range of thermoplastic polyolefin copolymers (also often generally referred to as resins, plastics and/or plastic resins) can be employed in the layers in the laminate film structures provided they can be formed into thin film or sheet layers and provide the desired physical properties. Alternative or preferred embodiments of the invention may employ one or more of the specific types of thermoplastic polyolefin copolymers and/or specific thermoplastic polyolefin copolymers in specific layers, as will be discussed further below.

The polyolefin copolymers useful in the practice of this invention are preferably polyolefin interpolymers or copolymers, more preferably ethylene/alpha-olefin interpolymers. These interpolymers have an α-olefin content needed to provide the prescribed density, generally of at least about 15, preferably at least about 20 and even more preferably at least about 25, weight percent (wt %) based on the weight of the interpolymer. These interpolymers typically have an α-olefin content of less than about 50, preferably less than about 45, more preferably less than about 40 and even more preferably less than about 35, wt % based on the weight of the interpolymer. The presence of an α-olefin and content is measured by ¹³C nuclear magnetic resonance (NMR) spectroscopy using the procedure described in Randall (Rev. Macromol. Chem. Phys., C29 (2&3)). Generally, the greater the α-olefin contents of the interpolymer, the lower the density and the more amorphous the interpolymer.

The α-olefin is preferably a C₃₋₂₀ linear, branched or cyclic α-olefin. Examples of C₃₋₂₀ α-olefins include propene, 1-butene, 4-methyl-1-pentene, 1-hexene, 1-octene, 1-decene, 1-dodecene, 1-tetradecene, 1-hexadecene, and 1-octadecene. The α-olefins can also contain a cyclic structure such as cyclohexane or cyclopentane, resulting in an α-olefin such as 3-cyclohexyl-1-propene (allyl cyclohexane) and vinyl cyclohexane. Although not α-olefins in the classical sense of the term, for purposes of this invention certain cyclic olefins, such as norbornene and related olefins, are α-olefins and can be used in place of some or all of the α-olefins described above. Similarly, styrene and its related olefins (for example, α-methylstyrene, etc.) are α-olefins for purposes of this invention. However, acrylic and methacrylic acid and their respective ionomers, and acrylates and methacrylates, and other similarly polar or polarizing unsaturated comonomers are not α-olefins for purposes of this invention. Illustrative polyolefin copolymers include ethylene/propylene, ethylene/butene, ethylene/1-hexene, ethylene/1-octene, ethylene/styrene, and the like. Ethylene/acrylic acid (EAA), ethylene/methacrylic acid (EMA), ethylene/acrylate or methacrylate, ethylene/vinyl acetate and the like copolymers similarly having polar or polarizing unsaturated comonomers are not thermoplastic polyolefin copolymers or interpolymers for purposes of the scope of this invention. Illustrative terpolymers that can be thermoplastic polyolefin copolymers or interpolymers for purposes of the scope of this invention include ethylene/propylene/1-octene, ethylene/propylene/butene, ethylene/butene/1-octene, and ethylene/butene/styrene. The copolymers can be random or blocky.

In general, relatively low density thermoplastic polyolefin copolymers are useful in the practice of this invention. In general, these are the “base” polymers that are grafted or functionalized to contain alkoxysilane. Typically they would have a density of less than about 0.910, preferably less than about 0.905, more preferably less than about 0.890, even more preferably less than about 0.880 and even more preferably less than about 0.875, grams per cubic centimeter (g/cm³). There is not, in most cases, a strict lower limit for the density of the polyolefin copolymers, but, for purposes of typical commercial processes of production, pelletizing, handling and/or processing of the resin, they will typically have a density greater than about 0.850, preferably greater than about 0.855 and more preferably greater than about 0.860, g/cm³. Density is measured by the procedure of ASTM D-792. These relatively low density polyolefin copolymers are generally characterized as semi-crystalline, flexible, resistant to water vapor transmission and having good optical properties, e.g., high transmission of visible and UV-light and low haze.

In general, the thermoplastic polyolefin copolymers useful in the practice of this invention desirably exhibit a melting point of less than about 105° C. in the case of those having a random structure but up to and including melting points of about 125° C. in the case of thermoplastic polyolefin copolymers having a block-type structure, as will be discussed further below. The melting points of the thermoplastic polyolefin copolymers can be measured, as known to those skilled in the art, by differential scanning calorimetry (“DSC”), which can also be used to determine the glass transition temperatures (“Tg”) as mentioned below. Further features of these copolymers that are also desirable include optionally, one or more of the following properties:
a 2% secant modulus of less than about 150 megaPascal (MPa) (as measured by ASTM D-790, and
a glass transition temperature (Tg) of less than about −35° C. as measured by DSC.

The polyolefin copolymers useful in the practice of this invention typically have a melt index of greater than or equal to about 0.10, preferably greater than or equal to about 1 gram per 10 minutes (g/10 min) and less than or equal to about 75 and preferably of less than or equal to about 10 g/10 min. Melt index is measured by the procedure of ASTM D-1238 (190° C./2.16 kg).

More specific examples of the polyolefin copolymers useful in this invention prior to or excluding the alkoxysilane incorporation include very low density polyethylene (VLDPE) (e.g., FLEXOMER® ethylene/1-hexene polyethylene made by The Dow Chemical Company), homogeneously branched, linear ethylene/alpha-olefin copolymers (e.g. TAFMER® by Mitsui Petrochemicals Company Limited and EXACT® by Exxon Chemical Company), homogeneously branched, substantially linear ethylene/alpha-olefin polymers (e.g., AFFINITY® and ENGAGE® polyethylene available from The Dow Chemical Company), and olefin block copolymers (OBC's) such as those described in U.S. Pat. No. 7,355,089 (e.g., INFUSE® available from The Dow Chemical Company). Specific preferred types of polyolefin copolymers include olefin block-type copolymers (OBC) and homogeneously branched, substantially linear ethylene copolymers (SLEP).

Regarding the preferred homogeneously branched substantially linear ethylene copolymers (SLEP's), these are examples of “random polyolefin copolymers” and the description of these types of polymers and their use in PV encapsulation films is discussed in 2008/036708 and they are more fully described in U.S. Pat. Nos. 5,272,236, 5,278,272 and 5,986,028, all of which are incorporated herein by reference. As is known, the SLEP-types of polyolefin copolymers are preferably made with a single site catalyst such as a metallocene catalyst or constrained geometry catalyst. These polyolefin copolymer typically have a melting point of less than about 95° C., preferably less than about 90° C., more preferably less than about 85° C., even more preferably less than about 80° C. and still more preferably less than about 75° C.

Similarly preferred are the olefin block copolymer (OBC) types of polyolefin copolymers, which are examples of “block-type polyolefin copolymers” and are typically made with chain shuttling-types of catalysts. The description of these types of polymers in their use in PV encapsulation films is discussed in 2008/036707, incorporated herein by reference. These block-types of polyolefin copolymers typically have a melting point of less than about 125° C. and preferably from about 115 to about 125° C.

For other types of polyolefin copolymers made with multi-site catalysts, e.g., Ziegler-Natta and Phillips catalysts, the melting point is typically from about 115 to about 135° C. The melting point is measured by differential scanning calorimetry (DSC) as described, for example, in U.S. Pat. No. 5,783,638. Polyolefin copolymers with a lower melting point often exhibit desirable flexibility and thermoplasticity properties useful in the fabrication of the modules of this invention. Similarly suitable is an ethylene-based block-type polymer as described in U.S. Pat. No. 5,798,420 and having an A block and a B block, and if a diene is present in the A block, a nodular polymer formed by coupling two or more block polymers.

Blends of any of the above thermoplastic polyolefin copolymer resins can also be used in this invention and, in particular, the thermoplastic polyolefin copolymers can be blended or diluted with one or more other polymers to the extent that the polymers are (i) miscible with one another, (ii) the other polymers have little, if any, impact on the desirable properties of the polyolefin copolymer, e.g., optics and low modulus, and (iii) the thermoplastic polyolefin copolymers of this invention constitute at least about 70, preferably at least about 75 and more preferably at least about 80 weight percent of the blend. Preferably, the blend itself also possesses the density, melt index and melting point properties noted above.

The alkoxysilane-containing thermoplastic polyolefin copolymers used for the films of this invention require, of course, alkoxysilane groups that are grafted or otherwise bonded into the thermoplastic polyolefin copolymer. Alkoxysilane groups can be incorporated into the thermoplastic polyolefin resin as generally described above using known monomeric reactants in a polymerization process, known grafting techniques, or other functionalization techniques. Any alkoxysilane group-containing compound or monomer that will effectively improve the adhesion performance of the thermoplastic polyolefin resin and can be grafted/incorporated therein and subsequently crosslinked, can be used in the practice of this invention.

Grafting of a graftable alkoxysilane compound to a suitable polyolefin copolymer has been found to be very well suited for obtaining the desired combination of polyolefin copolymer properties and alkoxysilane content. Suitable alkoxysilanes for alkoxysilane grafting and the crosslinking process include alkoxysilanes having an ethylenically unsaturated hydrocarbyl group and a hydrolyzable group, particularly the alkoxysilanes of the type which are taught in U.S. Pat. No. 5,824,718. It should be understood that as used herein:
the term “alkoxysilane” as grafted or in a graftable compound, refers to bonded alkoxysilane groups represented by the following formula:

—CH₂—CHR¹—(R²)ₘ—Si(R³)₃₋ₙ(OR⁴)ₙ I
and, the term “graftable alkoxysilane compound” and referring to “alkoxysilane” compounds before grafting refers to alkoxysilane compounds that can be described by the following formula:

CH₂═CR¹—(R²)ₘ—Si(R³)₃₋ₙ(OR⁴)ₙ II,
where, in either case I or II:
   R¹ is H or CH₃;
   R² is alkyl, aryl, or hydrocarbyl containing from 1 to 20 carbon atoms and may also include other functional groups, such as esters, amides, and ethers, among others;
   m is 0 or 1;
   R³ is alkyl, aryl, or hydrocarbyl containing from 1 to 20 carbon atoms;
   R⁴ is alkyl or carboxyalkyl containing from 1 to 6 carbon atoms (preferably methyl or ethyl);
   n is 1, 2, or 3 (preferably 3).

Suitable alkoxysilane compounds for grafting include unsaturated alkoxysilanes where the ethylenically unsaturated hydrocarbyl groups in the general formula above, can be a vinyl, allyl, isopropenyl, butenyl, cyclohexenyl, or (meth)acryloxyalkyl (refers to acryloxyalkyl and/or methacryloxyalkyl) group, the hydrolyzable group, denoted as OR⁴ in the general formula, can be methoxy, ethoxy, propoxy, butoxy, formyloxy, acetoxy, proprionyloxy, and alkyl- or arylamino groups and the saturated hydrocarbyl group, denoted as R³ in the general formula, if present can be methyl or ethyl. These alkoxysilanes and their method of preparation are more fully described in U.S. Pat. No. 5,266,627. Preferred alkoxysilane compounds include vinyltrimethoxysilane (VTMOS), vinyltriethoxysilane (VTEOS), allyltrimethoxysilane, allyltriethoxysilane, 3-acryloylpropyltrimethoxysilane, 3-acryloylpropyltriethoxysilane, 3-methacryloylpropyltrimethoxysilane, and 3-methacryloylpropyltriethoxysilane and mixtures of these silanes.

The amount of alkoxysilane needed in resins and films for the practice of this invention, can vary depending upon the nature of the thermoplastic polyolefin resin, the alkoxysilane, the processing conditions, the grafting efficiency, the amount of adhesion required in the ultimate application, and similar factors. The outcome desired from incorporating sufficient amounts of alkoxysilane groups is to provide sufficient adhesion prior to cross-linking and, following crosslinking, to provide necessary resin physical properties. In general, the grafted silane level needs to be sufficient in the thermoplastic polyolefin copolymer film surface contacting an adjacent layer to have adequate adhesion to the adjacent layer for the given application. For example, some applications, such as some of the photovoltaic cell laminate structures, can require an adhesive strength to a glass layer of at least about 5 Newtons per millimeter (“N/mm”) as measured by the 180 degree peel test. The 180-degree peel test is generally known to practitioners. Other applications or structures may require lower adhesive strength and correspondingly lower silane levels.

For the desired thermoplastic polyolefin copolymer film physical properties after cross-linking, it is typically necessary to obtain a gel content in the thermoplastic polyolefin resin, as measured by ASTM D-2765, of at least 40, preferably at least 50 and more preferably at least 60 and even more preferably at least 70, percent. Typically, the gel content does not exceed 90 percent.

With the adhesion and cross-linking goals in mind, there is preferably at least 0.1 percent by weight alkoxysilane in the grafted polymer, more preferably at least about 0.5% by weight, more preferably at least about 0.75% by weight, more preferably at least about 1% by weight, and most preferably at least about 1.2% by weight. Considerations of convenience and economy are usually the two principal limitations on the maximum amount of grafted alkoxysilane used in the practice of this invention. Typically, the alkoxysilane or a combination of alkoxysilanes, is added in an amount such that the alkoxysilane level in the grafted polymer is 10 percent by weight or less, more preferably less than or equal to about 5% by weight, more preferably less than or equal to about 2% by weight in the grafted polymer. The level of alkoxysilane in the grafted polymer can be determined by first removing the unreacted alkoxysilane from the polymer and then subjecting the resin to neutron activation analysis of silicon. The result, in weight percent silicon, can be converted to weight percent grafted alkoxysilane.

As mentioned above, grafting of the alkoxysilane to the thermoplastic polyolefin polymer can be done by many known suitable methods, such as reactive extrusion or other conventional method. The amount of the graftable alkoxysilane compound needed to be employed in the grafting reaction obviously depends upon the efficiency of the grafting reaction and the desired level of grafted alkoxysilane to be provided by the grafting reaction. The amount needed to be employed can be calculated and optimized by simple experimentation and knowing that the grafting reaction typically has an efficiency of about 60%. Thus, obtaining the desired level of grafted alkoxysilane usually requires incorporation of an excess of about 40%.

Graft initiation and promoting techniques are also generally well known and include by the known free radical graft initiators such as, for example, peroxides and azo compounds, or by ionizing radiation, etc. Organic free radical graft initiators are preferred, such as any one of the peroxide graft initiators, for example, dicumyl peroxide, di-tert-butyl peroxide, t-butyl perbenzoate, benzoyl peroxide, cumene hydroperoxide, t-butyl peroctoate, methyl ethyl ketone peroxide, 2,5-dimethyl-2,5-di(t-butyl peroxy)hexane, lauryl peroxide, and tert-butyl peracetate. A suitable azo compound is azobisisobutyl nitrile. While any conventional method can be used to graft the alkoxysilane groups to the thermoplastic polyolefin polymer, one preferred method is blending the two with the graft initiator in the first stage of a reactor extruder, such as a Buss kneader. The grafting conditions can vary, but the melt temperatures are typically between 160 and 260° C., preferably between 190 and 230° C., depending upon the residence time and the half life of the initiator.

As mentioned above, obtaining the improved encapsulating films according to the present invention involves using an alkoxysilane-containing thermoplastic polyolefin copolymer with the necessary low melt strength. It has been theorized that the prior art free radical initiated alkoxysilane compound grafting produced unacceptably high melt strength and attendant excessive shrinkage problems in the use of the encapsulation films. Various factors and techniques that will be discussed further below can be utilized to obtain the preferred low melt strength levels, in turn providing less shrinkage in the alkoxysilane-grafted polyolefin films for the encapsulation films according to the present invention.

It has been found that the desired melt strength for the silane-containing polyolefins for the resins and encapsulation films according to the present invention should be less than about 30 centiNewtons (“cN”) at 150° C., preferably less than about 25 cN at 150° C., and more preferably less than about 20 cN at 150° C. In general, the melt strength needs to be at least about 2 cN at 150° C., preferably at least about 4 cN at 150° C. As is generally known to practitioners in the field of olefin polymers, melt strength can be determined by techniques such as extensional rheology testing.

For example, melt strength can be measured in this way using a Göettfert Rheotens 71.97 rheology test unit (available from Göettfert Inc.; Rock Hill, S.C.). In this type of unit, the polymer being tested is melt fed with a Goettfert Rheotester 2000 capillary rheometer equipped with a flat entrance angle (180 degrees) of length of 30 mm and diameter of 2 mm. The pellets were fed into the barrel (L=300 mm, Diameter=12 mm), compressed and allowed to melt for 10 minutes before being extruded at a constant piston speed of 0.265 mm/s, which corresponds to a wall shear rate of 38.2 s⁻¹ at the given die diameter. The extrudate passed through the wheels of the Rheotens located at 100 mm 455 below the die exit and was pulled by the wheels downward at an acceleration rate of 2.4 mm/s². The force (in cN) exerted on the wheels was recorded as a function of the velocity of the wheels (in mm/s). Melt strength is reported as the peak or the plateau force (cN) before the strand broke.

In cases where a free radical initiated grafting reaction is taught for use to incorporate the alkoxysilane for PV encapsulation films, the general prior art teachings of free radical initiators have been found to promote byproduct and/or premature chain coupling reactions and yield higher than needed melt strength in the polymers. In such cases, one technique according to the present invention to obtain/maintain a desired low melt strength in the alkoxysilane-containing thermoplastic polyolefin copolymer is to employ preferred molar ratios of the graftable alkoxysilane compound to free radical initiator (“silane:initiator ratio”). In this ratio, the number of “moles” of free radical initiator actually refers to the equivalents of free radicals that are generated. For example, the “molar” amount of free radicals that can be generated from 2.0 grams of 2,5-dimethyl-2,5-di(tert-butylperoxy)hexane is 0.028 moles. The molecular weight of 2,5-dimethyl-2,5-di(tert-butylperoxy)hexane is 290.45 g/mole and each molecule generates four equivalents of free radicals (based on the starting molecule containing two dialkylperoxy groups and each dialkylperoxy group forms two alkoxy free radicals).

In these cases, based upon using an amount of graftable alkoxysilane compound determined to provided the needed levels of alkoxysilane as described above in the grafting reaction, it has been found suitable to have a silane:initiator molar ratio of at least about 20:1, more preferably at least about 25:1, more preferably at least about 30:1, more preferably at least about 35:1 and most preferably at least about 40:1. With regard to the upper limits for the silane:initiator ratio, although it has been found that with the use of higher silane:initiator ratios the melt strength is maintained desirably low, alkoxysilane compound usage becomes inefficient and residual ungrafted alkoxysilane compound levels become unacceptably high. In that regard, silane:initiator ratios are generally less than about 200:1, preferably less than about 150:1, more preferably less than 125:1, more preferably less than 100:1.

The alkoxysilane-containing thermoplastic polyolefin copolymer films can be prepared according to processes and techniques that are generally known and using equipment and technology that are commercially available and suitable for preparation of the desired products. In addition to utilizing the silane:initiator molar ratios as described above, other known techniques may also be employed to reduce the orientation and resulting shrinkage in the film layers as much as possible. These techniques include but are not limited to:
the use of annealing steps,
film die lip gap adjustments, and
higher film extrusion temperatures.

In whatever fashion the films are prepared, the films according to the invention and films employed to prepare the laminate structures according to the invention are designed to avoid orientation that would result in detrimental film shrinkage when using the films in PV modules or other applications. Preferably, it is desired to provide the films according to the present invention without use of inefficient and expensive annealing steps. For the films to be generally acceptable, minimize cell movement and maintain good adhesion in the making of PV modules and other similar types of laminate structures, it has been found that machine direction (MD) shrinkage needs to be reduced to levels of less than or equal to about 50%, preferably less than or equal to about 30%, more preferably less than or equal to about 25%, more preferably less than or equal to about 20% and most preferably less than or equal to about 15%. As used herein, the shrinkage data is measured on a 5″×5″ (12.7 cm×12.7 cm) film (457 μm thick). The sample is cut and placed on the top of a talc-covered craft paper and then placed in an oven set at 140° C. The specimen/paper is removed from the oven after 10 minutes and allowed to be cooled at the room temperature. The length of the film is measured in the machine direction (MD) and the transverse direction (TD) and the shrinkage is calculated in both directions. Transverse direction (TD) orientation and shrinkage can occur, is similarly undesirable and should be reduced to similar levels. However, for most films and film production processes, it is significantly less than MD and very unlikely to be the cause of the most significant undesired shrinkage problems.

The alkoxysilane-containing polyolefin copolymers as described above are typically and preferably utilized as the sole component make up the complete thickness of the encapsulation films according to the present invention. However, for cost savings or other desired performance effects, laminate or layered films having one or preferably both facial surface layers prepared from such copolymers are also possible provided that the necessary overall film performance and properties (light transmission, adhesion, physical properties, shrinkage etc.) are still obtained.

### Other Additives

The polymeric materials of this invention can comprise additives other than or in addition to the alkoxysilane crosslinking catalyst. For example, such other additives include UV absorbers, UV stabilizers and processing stabilizers. UV absorbers can include, for example, a benzophenone derivative such as Cyasorb UV-531. The UV-stabilizers include hindered phenols such as Cyasorb UV2908 and hindered amines such as Cyasorb UV 3529, Hostavin N30, Univil 4050, Univin 5050, Chimassorb UV 119, Chimassorb 944 LD, Tinuvin 622 LD and the like. The phosphorus-containing stabilizer compounds include trivalent phosphorus compounds, phosphonites (PEPQ) and phosphites (Weston 399, TNPP, P-168 and Doverphos 9228). The amount of UV-stabilizer is typically from about 0.1 to 0.8%, and preferably from about 0.2 to 0.5%. The amount of processing stabilizer is typically from about 0.02 to 0.5%, and preferably from about 0.05 to 0.15%.

Still other additives include, but are not limited to, antioxidants (e.g., hindered phenolics such as Irganox® 1010 made by Ciba Geigy Corp.), cling additives (e.g., polyisobutylene), anti-blocks, anti-slips, pigments and fillers (clear if transparency is important to the application). In-process additives, e.g. calcium stearate, water, etc., may also be used. These and other potential additives are used in the manner and amount as is commonly known in the art.

### Glass

When used in certain embodiments of the present invention, “glass” refers to a hard, brittle, transparent solid, such as that used for windows, many bottles, or eyewear, including, but not limited to, soda-lime glass, borosilicate glass, acrylic glass, sugar glass, isinglass (Muscovy-glass), or aluminum oxynitride. In the technical sense, glass is an inorganic product of fusion which has been cooled to a rigid condition without crystallizing. Many glasses contain silica as their main component and glass former.

Pure silicon dioxide (SiO₂) glass (the same chemical compound as quartz, or, in its polycrystalline form, sand) does not absorb UV light and is used for applications that require transparency in this region. Large natural single crystals of quartz are pure silicon dioxide, and upon crushing are used for high quality specialty glasses. Synthetic amorphous silica, an almost 100% pure form of quartz, is the raw material for the most expensive specialty glasses.

The glass layer of the laminated structure is typically one of, without limitation, window glass, plate glass, silicate glass, sheet glass, float glass, colored glass, specialty glass which may, for example, include ingredients to control solar heating, glass coated with sputtered metals such as silver, glass coated with antimony tin oxide and/or indium tin oxide, E-glass, SOLEX™ glass (available from PPG Industries of Pittsburgh, Pa.) and TOROGLASS™.

Alternatively, for one or more of the cover, top and/or back layers as described herein, alternatively or in addition to layer(s) of the above types of glass, one or more of the known rigid or flexible sheet materials, may also be selected, including for example, materials such as polycarbonate, acrylic polymers, a polyacrylate, a cyclic polyolefin such as ethylene norbornene, metallocene-catalyzed polystyrene, polyethylene terephthalate, polyethylene naphthalate, fluoropolymers such as ETFE (ethylene-tetrafluoroethlene), PVF (polyvinyl Fluoride), FEP (fluoroethylene-propylen), ECTFE (ethylene-chlorotrifluoroethylene), PVDF (polyvinylidene fluoride), and many other types of plastic, polymeric or metal materials, including laminates, mixtures or alloys of two or more of these materials. The location of particular layers and need for light transmission and/or other specific physical properties would determine the specific material selections.

### Laminated Structures

The films of the present invention can be used to construct laminated structures, such as glass-laminated light transmitting structures, including photovoltaic or solar cell modules, in the same manner and techniques as the encapsulant materials known in the art, e.g., such as those taught in U.S. Pat. No. 6,586,271, US Patent Application Publication US2001/0045229 A1, WO 99/05206 and WO 99/04971, incorporated by reference herein. In general, the laminated structures of this invention are structures comprising in sequence, starting with the layer upon which the light intended to be received initially contacts, (i) a light-receiving top sheet layer, such as a glass layer, (ii) an alkoxysilane-containing thermoplastic polyolefin copolymer encapsulating film layer according to the present invention (optionally containing other internal layers or components not adversely or detrimentally affecting adhesion and light transmission), (iii) a photovoltaic cell, (iv) if needed, a second alkoxysilane-containing thermoplastic polyolefin copolymer encapsulating film layer (optionally according to the present invention) and, (v) if needed, a back layer comprising glass or other back layer substrate. In any case, in the lamination process to construct a laminated PV module, at least the following layers are brought into adhering contact:
a light-receiving top sheet layer (e.g., a glass layer) having an “exterior” light-receiving facial surface and an “interior” facial surface;
an alkoxysilane-containing thermoplastic polyolefin copolymer film having one facial surface directed toward the top sheet layer and one directed toward the light-reactive surface of the PV cell and encapsulating the cell surface;
a PV cell;
if needed, a second encapsulating film layer (optionally according to the present invention); and
a back layer comprising glass or other back layer substrate.

With the layers or layer sub-assemblies assembled in desired locations the assembly process typically requires a lamination step with heating and compressing at conditions sufficient to create the needed adhesion between the layers. In general, lamination temperatures will depend upon the specific thermoplastic polyolefin copolymer layer materials being employed and the temperatures necessary to achieve their adhesion. In general, at the lower end, the lamination temperatures need to be at least about 130° C., preferably at least about 140° C. and, at the upper end, less than or equal to about 170° C., preferably less than or equal to about 160° C.

In ways like this, these films can be used as “skins” for the photovoltaic cells in photovoltaic modules, i.e., applied to one or both face surfaces of the cell as an encapsulant in which the device is totally enclosed within the films. The structures can be constructed by any one of a number of different methods. For example, in one method the structure is simply built layer upon layer, e.g., the first alkoxysilane-containing polyolefin encapsulating film layer is applied in any suitable manner to the top sheet layer, followed by the application of the photovoltaic cell, second encapsulating film layer and back layer.

In one embodiment, the photovoltaic module comprises (i) at least one photovoltaic cell, typically a plurality of such devices arrayed in a linear or planar pattern, (ii) at least one cover sheet (e.g., glass) on the surface intended for light to contact, typically a cover sheet over both face surfaces of the device, and (iii) at least one encapsulation film layer according to the present invention. The encapsulation film layer(s) are typically disposed between the cover sheet(s) and the cells and exhibit good adhesion to both the device and the cover sheet, low shrinkage, and good transparency for solar radiation, e.g., transmission rates in excess of at least about 85, preferably at least about 90, preferably in excess of 95 and even more preferably in excess of 97, percent as measured by UV-vis spectroscopy (measuring absorbance in the wavelength range of about 250-1200 nanometers. An alternative measure of transparency is the internal haze method of ASTM D-1003-00. If transparency is not a requirement for operation of the electronic device, then the polymeric material can contain opaque filler and/or pigment.

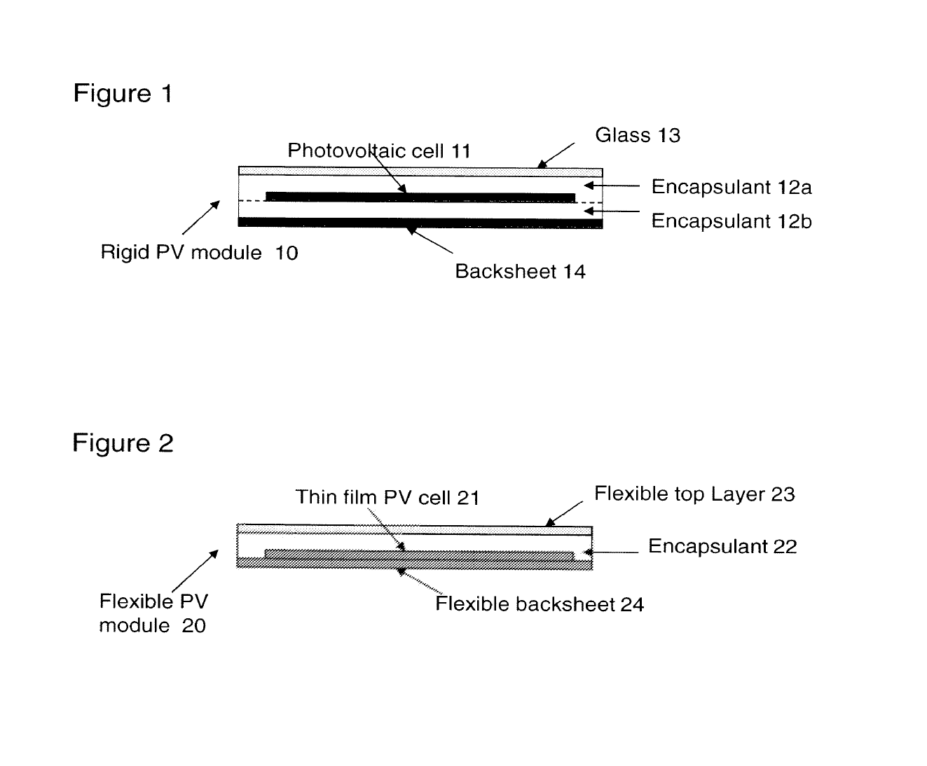

In FIG. 1 rigid PV module 10 according to the present invention comprises photovoltaic cell 11 according to the present invention (in this case having a light-reactive or effective surface directed or facing upward in the direction of the top of the page) surrounded or encapsulated by a transparent protective encapsulating film (combination of layers 12a and 12b) which is typically a combination of two “sandwiching” layers 12a and 12b. The interior surface of the light-receiving glass cover sheet 13 is in adhering contact with a front facial surface of the encapsulating film layer disposed over and in adhering contact with PV cell 11. Backskin or back sheet 14, e.g., a second glass cover sheet or another substrate of any kind, supports a rear surface of the portion of the encapsulating film layer 12 disposed on a rear surface of PV cell 11. Back sheet layer 14 (and even encapsulating sub-layer 12b) need not be transparent if the surface of the PV cell to which it is opposed is not effective, i.e., reactive to sunlight. In this embodiment, encapsulating film 12 encapsulates PV cell 11, preferably by a “sandwich” of two layers. The thicknesses of these layers, both in an absolute context and relative to one another, are not critical to this invention and as such, can vary widely depending upon the overall design and purpose of the module. Typical thicknesses for protective layer 12 are in the range of about 0.125 to about 2 millimeters (mm), and for the glass cover sheet and back sheet layers in the range of about 0.125 to about 1.25 mm. The thickness of the electronic device can also vary widely.

In FIG. 2 flexible PV module 20 according to the present invention comprises thin film photovoltaic cell 21 with its single light-reactive surface (directed upward in the direction of the top of the page) over-lain by transparent protective encapsulating film layer 22 according to the present invention comprising a thermoplastic polyolefin copolymer. Glazing/top layer 23 covers and is adhered to a front surface of the portion of the encapsulating film layer disposed over and in adhering contact with thin film PV cell 21. Flexible backskin or back sheet 24, e.g., a second protective layer or another flexible substrate of any kind, supports the bottom surface of thin film PV 21. Backskin layer 24, which can be the same as or similar to the encapsulating layers need not be transparent if the surface of the thin film cell which it is supporting is not reactive to sunlight. In this embodiment, protective layer 22 does not entirely encapsulate both sides of thin film photovoltaic cell 21 on both sides. The overall thickness of a typical rigid or flexible PV cell module will typically be in the range of about 5 to about 50 mm.

The films used for the modules described in FIGS. 1 and 2 can be constructed by any number of different methods, typically a film or sheet co-extrusion method such as blown-film, modified blown-film, calendaring and casting. For constructing the modules, in one method and referring to FIG. 1, protective layer(s) 12 is formed by first providing (preferably by extruding) a thermoplastic polyolefin copolymer film according to the invention over and onto the top light-reactive surface of the PV cell (directed toward the top of the page) and either simultaneously with or subsequent to providing the first film, providing (again, preferably by extruding) the same, or different, thermoplastic polyolefin copolymer over and onto the back surface of the cell (facing the bottom of the page). Once the protective film is attached to the PV cell, the glass cover sheet and back sheet layer can be attached in any convenient manner, e.g., extrusion, lamination, etc., to the protective layer, with or without an adhesive. Either or both external surfaces of the protective layer, i.e., the surfaces opposite the surfaces in contact with the PV cell and facing out from the cell, can be embossed or otherwise treated to enhance adhesion to the glass and back sheet layers. The module of FIG. 2 can be constructed in a similar manner, except that the back sheet layer 24 and PV cell 21 are attached directly to one another, with or without an adhesive, either prior or subsequent to the attachment of the protective layer 22 to the PV cell.

Other applications in which the method of this invention is useful include as a layer in safety glass, a sealant for insulated glass, as a coating for glass (e.g., to provide a visible or UV-light shield), and as a general adhesive for glass.

The following examples further illustrate the invention. Unless otherwise indicated, all parts and percentages are by weight.

### Experiments 1-6

Resins are prepared as described below using ENGAGE™ 8200 brand thermoplastic polyolefin copolymer base resin as summarized below.

ENGAGE™ 8200 Brand Thermoplastic Polyolefin Copolymer
Density—0.870 grams per cubic centimeter (g/cc) as measured by ASTM D792.
Melt Index—5 grams per 10 minutes (g/10 min) as measured by ASTM D-1238 (190° C./2.16 kg).
Melting point—59° C. as measured by differential scanning calorimetry,
2% secant modulus—1570 psi (10.8 MPa) as measured by ASTM D-790,
α-olefin—1-octene
Tg of −63.4° F. (−53° C.) as measured by differential scanning calorimetry.

The vinyl alkoxysilane was vinyltrimethoxysilane (“VTMS”, Dow Corning Z-6300—now referred to as Xiameter OFS-6300) and the peroxide free radical graft initiator was 2,5-di-tert-butylperoxy-2,5-dimethylhexane (Luperox-101). The resin formulations also contained standard UV and antioxidant additives. The six formulations described in Table 1 were prepared and used to make alkoxysilane-grafted polyolefin copolymer film resins for various tests. The group of resins included one formulation of thermoplastic polyolefin copolymer only (no alkoxysilane, no peroxide) for studying the effect of processing on the resin, and five formulations with the silane:initiator ratio ranging from 10:1 to 80:1.

To perform the alkoxysilane grafting, the resin pellets, VTMS, and peroxide were premixed under nitrogen to imbibe the liquids into the pellets. The imbibed resin pellets were subjected to reactive extrusion through an 18-mm Leistritz twin screw extruder. The drive unit for the extruder was run at 200 rpm, which results by gear transfer to a screw speed of 250 rpm. The temperature settings for zones 1 through 5 were 150° C., 175° C., 190° C., 190° C., and 210° C.; the die was heated to 210° C. The imbibed materials were fed to the extruder through a twin-auger K-Tron feeder model #K2VT20.

Neutron activation analysis was used to determine the level of grafted alkoxysilane in the products. The grafted alkoxysilane levels are listed in Table 1 as the weight percentage alkoxysilane that is grafted into the polymer. The melt strengths of the sample resins with different silane:initiator ratios were measured at 150° C. using a capillary rheometer combined with a Rheotens melt strength measurement device. The tensile force in the filament was determined by measuring the vertical force on the rotating drum. The melt strength results are shown in Table 1, below. As shown, versus the ungrafted sample (Experiment 1), the silane grafted samples (Experiments 2-6) show increased melt strengths. Ungrafted, the melt strength is about 2 cN for the thermoplastic polyolefin copolymer resin. Use of the higher silane:initiator ratios in Experiments 4-6 provide desired lower melt strength levels (from about 15 to about 21). Use of the highest initiator levels (lowest silane:initiator ratios—Experiments 2 and 3) give the highest melt strength levels of about 30 cN at 150 C.

TABLE 1
Materials and formulations

| | | | Wt. % | | | |
|---|---|---|---|---|---|---|
| | | | Initiator | | | Melt |
| | Wt. % | Wt. % | (Luperox- | | | Strength |
| | Engage | Silane | 101 | Silane:Initiator | VTMS graft | (cN) at |
| Expt. No. | 8200 | (VTMS) | Peroxide) | Molar Ratio | level (wt %) | 150° C. |
| 1 | 100.0 | 0 | 0.00 | — | 0 | 2 |
| 2 | 97.9 | 2 | 0.10 | 10 | 0.97 | >30 |
| 3 | 97.95 | 2 | 0.05 | 20 | 0.67 | >30 |
| 4 | 97.975 | 2 | 0.025 | 40 | 0.4 | 21 |
| 5 | 97.98 | 2 | 0.02 | 50 | 0.3 | 16 |
| 6 | 97.9875 | 2 | 0.0125 | 80 | 0.22 | 15 |

To determine the effect of silane:initiator ratio, DMS shear rheology data were obtained with an Advanced Rheometrics Expansion System (ARES) at 150° C. using pristine compression-molded samples of the film resins prepared above without any stabilizers. The measurements were made over the angular frequency range 0.1-100 rad/s. An N2 stream was circulated through the sample oven to minimize chain extension or crosslinking during the experiments. All of the samples were received as pellets and compression molded at 190° C. From the shear rheology measurements by DMS, the higher viscosities at low shear rates represent higher melt strengths. As shown in Table 2 below, the sample with the silane:initiator molar ratio of 10 shows the highest viscosity at low shear rate (highest melt strength), and the low shear rate viscosity (melt strength) decreases as the silane:initiator ratio increases; demonstrating lower melt strengths being obtained as the silane:initiator ratio increases.

TABLE 2
Low Shear Viscosities as a Function of Peroxide:Silane Ratios

| Expt. | Silane:initiator | viscosity at | viscosity at | viscosity at |
|---|---|---|---|---|
| No. | ratio | 0.1 (Pa-s) | 1 (Pa-s) | 10 (Pa-s) |
| 1 | Control | 4436 | 3786 | 2492 |
| 2 | 10 | 36861 | 13378 | 4321 |
| 3 | 20 | 22720 | 9981 | 3788 |
| 4 | 40 | 12851 | 7259 | 3333 |
| 5 | 50 | 11802 | 6963 | 3295 |
| 6 | 80 | 14002 | 7719 | 3486 |

### Experiments 7-9

The effect of the silane:initiator ratio on cast film shrinkage was examined on cast films prepared from film resin formulations as shown in Table 3 below. In this case, full formulations (with all typical additives) were used for the analysis. For the adhesion of these resins to the specific test glass materials used in these experiments, the grafted alkoxysilane levels need to be greater than >1% to have the adequate adhesion to glass (>5 N/mm measured by the 180 degree peel test) and the alkoxysilane level used for the grafting was increased and adjusted to obtain a sufficient grafted alkoxysilane level for the case of high silane:initiator ratio. The vinyl alkoxysilane was vinyltrimethoxysilane (“VTMS”, Dow Corning Z-6300) and the peroxide free radical graft initiator was 2,5-di-tert-butylperoxy-2,5-dimethylhexane (Luperox-101). The thermoplastic polyolefin copolymer was a blend of ENGAGE™ 8200 brand thermoplastic polyolefin copolymer as described in more detail above and ENGAGE™ 8440 brand thermoplastic polyolefin copolymer as described in more detail below:

ENGAGE™ 8440 Brand Thermoplastic Polyolefin Copolymer

Density—0.897 g/cc as measured by ASTM D792.

Melt Index—1.6 g/10 min ASTM D-1238 (190° C./2.16 kg).

Melting point—93° C. as measured by differential scanning calorimetry.

2% secant modulus—7880 psi (54.3 MPa) as measured by ASTM D-790,

α-olefin—1-octene

Tg of −27.4° F. (−33° C.) as measured by differential scanning calorimetry.

Materials were compounded with a ZSK-30 30-mm twin-screw, co-rotating extruder. The cast film process, as summarized in Table 4 below, includes alkoxysilane liquid injection directly into the extruder, grafting of alkoxysilane in the presence of peroxide, devolatilization of the unreacted alkoxysilane and film extrusion in a continuous process. Film thickness was targeted at 15 mils. The shrinkage of un-annealed films was measured based on ASTM D2732-03 (Standard Test Method for Unrestrained Linear Thermal Shrinkage of Plastic Film and Sheeting), and the results are shown in Table 3 below. The results indicate that cast film shrinkage in the machine direction (“MD”) direction decreased as the silane:initiator ratio increased. The film shrinkage was reduced from generally unacceptable levels of about 36% to acceptable levels in the ranges of 13% for a silane:initiator ratio of 40 and 20% for a silane:initiator ratio of 50. The adhesion of films 7-9 to glass was measured and observed to have good adhesion to glass, all meeting the adhesion strength target, i.e. no delamination using the 180-degree peel test at room temperature.

TABLE 3
Formulations and Results for Reactive Extrusion and Films 7-9

| | | | |
|---|---|---|---|
| Experiment No. | 7 | 8 | 9 |

| ENGAGE 8200 (wt %) | | 70.65 | 69.37 | 68.72 |
|---|---|---|---|---|
| ENGAGE 8440 (wt %) | | 27.48 | 26.98 | 26.73 |
| Silane (VTMS) (wt %) | | 1.78 | 3.6 | 4.5 |
| Initiator (Luperox 101) (wt %) | | 0.089 | 0.045 | 0.045 |
| Silane:Initiator ratio (molar) | | 10 | 40 | 50 |
| VTMS graft level (wt %) | | 1.50 | 1.50 | 1.52 |
| MD Shrinkage | (%) Average | −36.1 | −13.1 | −20.2 |
| | STDEV | 2.1 | 2.5 | 0.5 |
| TD Shrinkage | (%) Average | 0.3 | −3.1 | −2.5 |
| | STDEV | 0.4 | 0.9 | 1.0 |

The film casting processing conditions are listed in Table 4, below.

TABLE 4
Films 7-9 Cast Film Process Conditions

| Experiment No. | 7 | 8 | 9 |
|---|---|---|---|
| Zone 1 (° F.) | 300 | 300/300 | 300 |
| Zone 2 (° F.) | 329 | 325/325 | 325 |
| Zone 3 (° F.) | 352 | 350/351 | 350 |
| Zone 4 (° F.) | 349 | 350/353 | 354 |
| Die Heat Zone 1 (° C.) | 180 | 180/180 | 180 |
| Die Heat Zone 2 (° C.) | 184 | 180/179 | 182 |
| Die Heat Zone 3 (° C.) | 180 | 180/181 | 180 |
| Adaptor Heat (° C.) | 175 | 180/180 | 178 |
| RPM's | 46 | 44 | 44 |
| Amps | 14 | 16 | 16 |
| Pressure | 1120 | 1100 | 1120 |
| Chill Roll Speed (fpm) | 4.7 | 5 | 5 |
| Bottom Roll Temp (° F.) | 64 | 70/69 | 67 |
| Middle Roll Temp (° F.) | 63 | 70/67 | 65 |
| Top Roll Temp (° F.) | 65 | 70/65 | 68 |
| Die Gap (mil) | 22 | 22 | 22 |
| Chill Roll Gap (mil) | 18 | 18 | 18 |

### Experiments 10-15

Some additional un-annealed film samples were prepared and tested using a similar process and the material and film shrinkage test results are shown in Table 5.

ENGAGE™ 8450 Brand Thermoplastic Polyolefin Copolymer

Density—0.902 g/cc as measured by ASTM D792.

Melt Index—3 g/10 min ASTM D-1238 (190° C./2.16 kg).

Melting point—97° C. as measured by differential scanning calorimetry.

2% secant modulus—11000 psi (75.9 MPa) as measured by ASTM D-790.

α-olefin-1-octene.

Tg of −25.6° F. (−32° C.) as measured by differential scanning calorimetry.

Film formulations and film shrinkage data are shown in Table 5. The results indicate that lower amounts of shrinkage in MD direction were observed for films made with the higher silane:initiator ratios.

TABLE 5
Experiments 10-15; Formulations and Results

| | Experiment No. | | | | | |
|---|---|---|---|---|---|---|
| | 10 | 11 | 12 | 13 | 14 | 15 |
| ENGAGE 8450 | 98.055 | 96.455 | 97.230 | 96.405 | 97.230 | 98.005 |
| Silane (VTMS) | 1.900 | 3.500 | 2.700 | 3.500 | 2.700 | 1.900 |
| (wt %) | | | | | | |
| Initiator | 0.045 | 0.045 | 0.070 | 0.095 | 0.070 | 0.095 |
| (Luperox 101) | | | | | | |
| (wt %) | | | | | | |
| Silane/initiator | 21 | 39 | 19 | 18 | 19 | 10 |
| ratio (molar) | | | | | | |
| VTMS graft | 1.15 | 1.70 | 1.69 | 2.28 | 1.72 | 1.54 |
| level (wt %) | | | | | | |
| Melt Strength | 6.8 | 5.0 | 7.5 | 7.9 | 7.3 | 9.2 |
| (cN) at 150° C. | | | | | | |
| Shrinkage (MD | −20.0 | −12.7 | −21.4 | −25.0 | −23.7 | −32.6 |
| at 140° C./ | | | | | | |
| 10 min) | | | | | | |
| Shrinkage | −3.6 | −3.9 | −2.3 | −1.9 | −2.3 | −1.0 |
| (TD at 140° C./ | | | | | | |
| 10 min) | | | | | | |

To summarize, in the above data, the results show that reduced melt strength along with higher silane:initiator ratio lead to less film shrinkage and will provide improved encapsulated PV cells and PV modules.

TABLE 6
Experiments 10-15 Extruder Process Conditions

| | Experimental Film Resin | | | | | |
|---|---|---|---|---|---|---|
| | 10 | 11 | 12 | 13 | 14 | 15 |
| Feed Rate | 150 | 150 | 150 | 150 | 150 | 150 |
| (lb/h) | | | | | | |
| Screw Speed | 250 | 250 | 250 | 250 | 250 | 250 |
| (RPM) | | | | | | |
| Motor AMP | 188-198 | 180-191 | 182-192 | 189-193 | 182-192 | 197-205 |
| Extruder | 80-84 | 74-77 | 77-81 | 78-80 | 77-81 | 81-85 |
| Load/Torque | | | | | | |
| (%) | | | | | | |
| Zone #2 | 27 | 27 | 27 | 27 | 27 | 27 |
| Temperature | | | | | | |
| (° C.) | | | | | | |
| Zone #3 | 150 | 150 | 146 | 150 | 146 | 150 |
| Temperature | | | | | | |
| (° C.) | | | | | | |
| Zone #4 | 190 | 190 | 186 | 190 | 186 | 191 |
| Temperature | | | | | | |
| (° C.) | | | | | | |
| Zone #5 | 172 | 169 | 167 | 166 | 167 | 167 |
| Temperature | | | | | | |
| (° C.) | | | | | | |
| Zone #6 | 199 | 197 | 197 | 194 | 197 | 200 |
| Temperature | | | | | | |
| (° C.) | | | | | | |
| Zone #7 | 190 | 189 | 182 | 190 | 182 | 190 |
| Temperature | | | | | | |
| (° C.) | | | | | | |
| Zone #8 | 181 | 180 | 181 | 180 | 181 | 183 |
| Temperature | | | | | | |
| (° C.) | | | | | | |
| Zone #9 | 181 | 198 | 196 | 174 | 196 | 191 |
| Temperature | | | | | | |
| (° C.) | | | | | | |
| Zone #10 | 172 | 168 | 168 | 168 | 168 | 174 |
| Temperature | | | | | | |
| (° C.) | | | | | | |
| Zone #11 | 165 | 171 | 157 | 174 | 157 | 158 |
| Temperature | | | | | | |
| (° C.) | | | | | | |
| Die | 184 | 179 | 180 | NA | 180 | 179 |
| Temperature | | | | | | |
| (° C.) | | | | | | |
| H₂ | 20 | 20 | 19 | NA | 19 | 21 |
| Temperature | | | | | | |
| (° C.) | | | | | | |
| Zone 1 | 158 | 153 | 157 | NA | 157 | 167 |
| Temperature | | | | | | |
| (° C.) | | | | | | |
| Zone 3 | 188 | 195 | 196 | NA | 196 | 196 |
| Temperature | | | | | | |
| (° C.) | | | | | | |
| Cutter Speed | 2120 | 2120 | 2122 | NA | 2122 | 2121 |
| (RPM) | | | | | | |
| Die Pressure | 1196 | 1063 | 1151 | 1129 | 1151 | 1283 |
| (psig) | | | | | | |

TABLE 7
Experiments 10-15; Mini Cast Film Extruder Process Conditions

| | Experimental Film | | | | | |
|---|---|---|---|---|---|---|
| | 10 | 11 | 12 | 13 | 14 | 15 |
| Extruder Zone 1 (° F.) | 300 | 300 | 300 | 300 | 300 | 300 |
| Extruder Zone 2 (° F.) | 375 | 375 | 375 | 375 | 375 | 375 |
| Extruder Zone 3 (° F.) | 425 | 425 | 425 | 425 | 425 | 425 |
| Die Zone 1 (° F.) | 425 | 425 | 425 | 425 | 425 | 425 |
| Die Zone 2 (° F.) | 425 | 425 | 425 | 425 | 425 | 425 |
| Die Zone 3 (° F.) | 425 | 300 | 300 | 300 | 300 | 300 |
| Cast Roll (fpm) | 6.5 | 6.5 | 6.5 | 6.5 | 6.5 | 6.2 |
| Web Width (in) | 8 | 8 | 8 | 8 | 8 | 8 |
| Thickness (mils) | 18 | 18 | 18 | 18 | 18 | 18 |
| Cast Roll (° F.) | 56 | 54 | 53 | 53 | 53 | 53 |
| Winder (%) | 40 | 40 | 40 | 40 | 40 | 40 |

Although the invention has been described in considerable detail through the preceding description, drawings and examples, this detail is for the purpose of illustration. One skilled in the art can make many variations and modifications without departing from the spirit and scope of the invention as described in the appended claims. All United States patents and published or allowed United States patent applications referenced above are incorporated herein by reference.

What is claimed is:

1. A thermoplastic, alkoxysilane-containing polyolefin copolymer comprising at least about 0.1 weight percent of alkoxysilane based on the total weight of the polyolefin, and having a melt strength of from about 2 to about 30 centiNewtons (“cN”) at 150° C.

2. A thermoplastic, alkoxysilane-grafted ethylene/α-olefin copolymer according to claim 1 comprising from about 0.1 to about 2.5 weight percent grafted alkoxysilane and having:
(i) a density of less than about 0.910 g/cc,
(ii) a melting point of less than about 105° C. if a random structure or less than about 125° C. if a block-type structure, and
(iii) optionally, one or more of:
(a) a 2% secant modulus of less than about 150 megaPascal (MPa),
(b) a Tg of less than about −35° C.

3. A grafting process for preparing a thermoplastic alkoxysilane-containing polyolefin copolymer according to claim 1 comprising the step of:
A. grafting from about 0.1 to about 2.5 weight percent alkoxysilane compound to a thermoplastic polyolefin copolymer using a free radical generating graft initiator material;
wherein the free radical generating graft initiator material is used in the grafting step in an amount that provides a molar ratio of alkoxysilane compound to free radical of at least about 20:1 or greater in the grafting reaction.

4. The process according to claim 3 wherein the graftable alkoxysilane compound is represented by the following formula II:
CH₂═CR¹—(R²)ₘ—Si(R³)₃₋ₙ(OR⁴)ₙ II
wherein:
R¹ is H or CH₃;
R² is alkyl, aryl, or hydrocarbyl containing from 1 to 20 carbon atoms and may also include other functional groups, such as esters, amides, and ethers, among others;
m is 0 or 1;
R³ is alkyl, aryl, or hydrocarbyl containing from 1 to 20 carbon atoms;
R⁴ is alkyl or carboxyalkyl containing from 1 to 6 carbon atoms (preferably methyl or ethyl); and
n is 1, 2, or 3 (preferably 3).

5. A grafting process according to claim 3 employing a thermoplastic ethylene/α-olefin copolymer characterized by: (i) a density of less than about 0.910 g/cc, (ii) a melting point of less than about 95 degrees C., and optionally, one or more of (iii)(a) a 2% secant modulus of less than about 150 megaPascal (MPa), (iii)(b) an α-olefin content of from at least about 15 to less than about 50 wt % based on the weight of the polymer, (iii)(c) a Tg of less than about −35 C, and (iii).

6. A thermoplastic, alkoxysilane-containing polyolefin copolymer film for photovoltaic cell encapsulation having at least one facial surface layer of a thermoplastic, alkoxysilane-containing polyolefin copolymer according to claim 1 and having a thickness of from about 200 to about 1000 micrometers (from about 8 to about 40 mils) and having a machine direction shrinkage value less than or equal to about 20%.

7. A photovoltaic module comprising:
A. at least one photovoltaic cell and
B. a layer of a film of a thermoplastic polyolefin copolymer according to claim 1 disposed over a light-reactive surface of the photovoltaic cell.

8. A photovoltaic module according to claim 7 further comprising:
C. a layer of a film of a thermoplastic polyolefin copolymer according to claim 1 disposed over the other surface of the photovoltaic cell and
D. front and back layers

9. A process for preparing a photovoltaic module comprising at least one photovoltaic cell having at least one light-reactive surface, at least one layer of glass, and at least one thermoplastic polyolefin copolymer encapsulating film according claim 1 above, the process comprising the steps of:
A. contacting a first facial surface of a first film according to claim 1 with the light-reactive facial surface of the photovoltaic cell having at least one light-reactive surface and encapsulating the cell surface;
B. contacting a first facial surface of a second film optionally according to claim 1 with the other facial surface of the photovoltaic cell and encapsulating the cell;
C. contacting a top sheet layer with the second facial surface of the encapsulating film(s) applied to the light-reactive surface of cell in Step A;
D. contacting a back sheet layer with the second facial surface of the film applied in Step B; and
E. lamination by compressing the layers with heating to a lamination temperature of from about 130° C. to about 170° C.
